(19) United States
(12) Patent Application Publication
(10) Pub. No.: US 2025/0194440 A1
(43) Pub. Date: Jun. 12, 2025

(54) ELECTROCHEMICAL MEMORY CELL, NEURAL NETWORK MEMORY INCLUDING THE ELECTROCHEMICAL MEMORY CELL

(71) Applicant: SK hynix Inc., Icheon-si (KR)

(72) Inventors: Won Tae KOO, Icheon-si (KR); Pil Hoon JUNG, Icheon-si (KR); Joong Sik KIM, Icheon-si (KR)

(21) Appl. No.: 18/582,323

(22) Filed: Feb. 20, 2024

(30) Foreign Application Priority Data
Dec. 11, 2023 (KR) 10-2023-0179063

(51) Int. Cl. H10N 70/20; G06N 3/04; H10B 63/00; H10N 70/00

(52) U.S. Cl. CPC H10N 70/253; G06N 3/04; H10B 63/00; H10N 70/011; H10N 70/245

(57) ABSTRACT

An electrochemical memory cell may include a plurality of nano patterns, a gate and an interface layer. The nano patterns may be stacked on an active region by a set gap. The gate may surround all surfaces of each of the nano patterns. The interface layer may be interposed between the nano patterns and the gate. The nano patterns may include a variable resistance material.

### CROSS-REFERENCE TO RELATED APPLICATION

The present application claims priority under 35 U.S.C. § 119 (a) to Korean application number 10-2023-0179063, filed on Dec. 11, 2023, in the Korean Intellectual Property Office, which is incorporated herein by reference in its entirety.

### BACKGROUND

### 1. Technical Field

Various embodiments generally relate to a semiconductor memory technology, and more particularly, to an electrochemical memory cell, a neural network memory device including the electrochemical memory cell.

### 2. Related Art

In von Neumann computer architecture, frequent movements of massive data between a processor and a memory may cause long delay times and high-power consumption. In order to solve these problems, an analog cross point array structure may be proposed.

The analog cross point array may include a plurality of memory cells programmed by a plurality of conductance. The analog cross point may calculate a vector-matrix multiplication and a vector outer product update using a time complexity in an analog way.

A non-volatile memory may be mainly used for a memory cell of an analog cross point array. Recently, as artificial synapse weights in the artificial neural network memory device become increasingly important, an electrochemical random access memory (ECRAM) may be widely used for the memory cell of an analog cross point array.

The electrochemical memory cell may perform a memory operation by an ion exchange with a channel in accordance with a gate voltage (or a gate current). In the electrochemical memory cell, an accurate ratio between a set resistance and a reset resistance may improve the operational speed and other characteristics.

### SUMMARY

According to example embodiments, there may be provided an electrochemical memory cell. The electrochemical memory cell may include a plurality of nano patterns, a gate and an interface layer. The nano patterns may be stacked on an active region by a set gap. The gate may surround surfaces of each of the nano patterns. The interface layer may be interposed between the nano patterns and the gate. The nano patterns may include a variable resistance material.

In example embodiments, at least one of the nano patterns, the gate and the interface layer may include a material generating ions in an electrochemical reaction to be used for a memory operation.

According to example embodiments, there may be provided a neural network memory. The neural network memory may include a plurality of electrochemical memory cells. Each of the electrochemical memory cells may include a lower layer, a channel region, a source, a drain, a gate and an interface layer. The lower layer may include an active region. The active region may have an upper surface formed by a first direction and a second direction that is substantially perpendicular to the first direction. The active region may be extended in the second direction. The channel region may be in portion of the active region. The source may be arranged on the active region at one side of the channel region. The drain may be arranged on the active region at the other side of the channel region. The gate may surround surfaces of a variable resistance pattern of the channel region. The gate may be extended in the first direction. The interface layer may be interposed between the channel region and the gate. The channel region may include a plurality of variable resistance patterns. The variable resistance patterns may be stacked and spaced apart by a set gap in a third direction substantially perpendicular to the upper surface of the lower layer.

In example embodiments, the gate and the interface layer may be positioned in a space between the variable resistance patterns, a space between a lowermost variable resistance pattern among the variable resistance patterns and the active region, and an upper surface of an uppermost variable resistance pattern among the variable resistance patterns and the gate.

In example embodiments, the interface layer may include an electrolyte layer and an ion storage layer. The electrolyte layer may be on the variable resistance patterns. The electrolyte layer may include an insulation material. The ion storage layer may be between the electrolyte layer and the gate. The ion storage layer may generate the ions for the memory operation in accordance with a direction of an electric field generated between the channel region and the gate to provide the variable resistance patterns with the ions. The ion storage layer may receive and store the ions for the memory operation from the variable resistance patterns.

According to example embodiments, there may be provided a method of manufacturing an electrochemical memory cell. In the method of manufacturing the electrochemical memory cell, an isolation layer may be formed in a lower layer to define an active region. At least one variable resistance layer and at least one sacrificial layer may be alternately stacked on the lower layer. The variable resistance layer and the sacrificial layer may be patterned to form a nano pattern structure corresponding to a shape of the active region. A dummy gate may be formed to surround a channel region of the nano pattern structure with the dummy gate. The nano pattern structure exposed by the dummy gate may be removed to expose the active region. A source and a drain may be formed on the exposed active region. The dummy gate may be removed to define a gate region. The sacrificial layer may be selectively removed to expose surfaces of a variable resistance pattern. An interface layer may be formed on the variable resistance pattern. A conductive layer may be formed on the interface layer to fill up the gate region, thereby forming a gate.

According to example embodiments, a memory cell of the neural memory device may use the electrochemical memory cell including the nano pattern having a GAA structure. Ion exchanges may be generated between all surfaces of the nano patterns and the gate so that the neural memory device may have improved integration degree, a high set/reset ratio, low power consumption and a rapid operation.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIG. 1 is a circuit diagram illustrating a neural network memory device in accordance with an embodiment of the disclosure;

FIGS. 2A and 2B are perspective views illustrating an electrochemical memory cell in accordance with embodiments of the disclosure;

FIGS. 3A and 3B are cross-sectional views illustrating a write operation of an electrochemical memory cell in accordance with embodiments of the disclosure;

FIGS. 4A and 4B are cross-sectional views illustrating a read operation of an electrochemical memory cell in accordance with embodiments of the disclosure;

FIG. 5 is a graph showing a conductance of a memory cell in accordance with an embodiment of the disclosure;

FIG. 6 is a graph showing variances of a conductance of a memory cell in accordance with an embodiment of the disclosure; and

FIG. 7 is a flow chart illustrating a method of manufacturing an electrochemical memory cell in accordance with an embodiment of the disclosure.

### DETAILED DESCRIPTION

Various embodiments of the present disclosure will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes, illustrated herein but may include deviations in configurations and shapes which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concepts. Although a few embodiments of the present invention will be shown and described, it will be appreciated by those of ordinary skill in the art that changes may be made in these embodiments without departing from the principles and spirit of the present invention.

As used herein, the term “configured” refers to a size, shape, material composition, orientation, or arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to a major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

In example embodiments, devices formed by a high temperature process and devices formed by a low temperature process may be provided to different substrates. Further, in order to reduce a thermal burden of the devices formed by the low temperature process, the devices formed by the low temperature process may be integrated after bonding the substrates to each other.

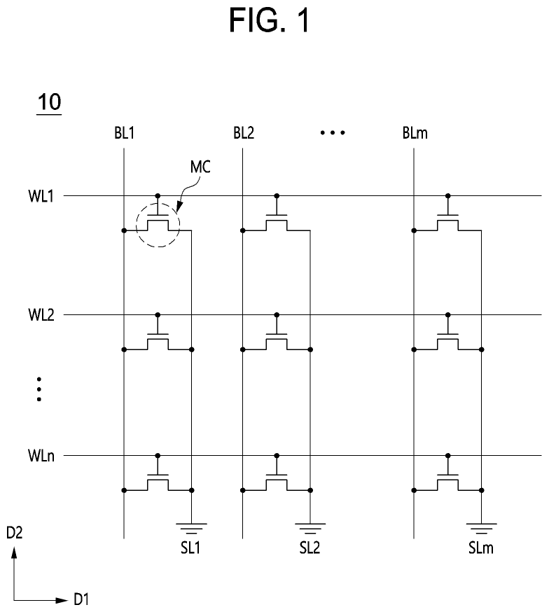

FIG. 1 is a circuit diagram illustrating a neural network memory device in accordance with example embodiments.

Referring to FIG. 1, a neural network memory device 10 of example embodiments may include a plurality of word lines WL1˜WLn and a plurality of bit lines BL1˜BLm that intersect the word lines WL1˜WLn. The neural network memory device 10 may further include a plurality of source lines SL1˜SLm.

For example, the plurality of word lines WL1˜WLn may be arranged parallel to each other in a first direction D1. The plurality of bit lines BL1˜BLm may be arranged parallel to each other in a second direction D2, which is substantially perpendicular to the first direction D1. The plurality of source lines SL1˜SLm may be extended in the first direction D1 or the second direction D2. In example embodiments, the plurality of source lines SL1˜SLm may be arranged in the second direction D2. Alternatively, the source lines SL1˜SLm may be commonly connected to a substrate bias line.

The neural network memory device 10 may include a plurality of memory cells MC. The plurality of memory cells MC may be arranged at intersecting portions of the plurality of word lines WL1˜WLn, the plurality of bit lines BL1˜BLm and the plurality of source lines SL1˜SLm, respectively.

Each of the memory cells MC may include three terminal type elements, respectively connected to one word line, one bit line and one source line. In example embodiments, the memory cell MC may have a switch and memory function including a gate, a drain and a source, as the three terminals. The gate may be electrically connected to a word line. The drain may be electrically connected to a bit line. The source may be electrically connected to a source line.

The gate may receive an operation voltage, such as program voltages for a set operation and a reset operation, and a read voltage. For example, a memory operation of the memory cell may be performed by resistance change of the memory cell according to an electrochemical reaction. The electrochemical reaction may be generated by ions that are generated in turn by the program voltages. The memory cells MC may be electrochemical memory cells. In the description below, the reference numeral MC may indicate an electrochemical memory cell.

The plurality of word lines WL1˜WLn may be connected to an input control block (not illustrated). A word line of a selected address may receive an operation voltage. The plurality of bit lines BL1˜BLm may be connected to an output control block (not illustrated) to sense a conductance of the memory cell at a selected address. A resistance of the memory cell MC may be determined by an output current from the memory cell MC. The resistance of the memory cell may mean a conductance of the memory cell MC.

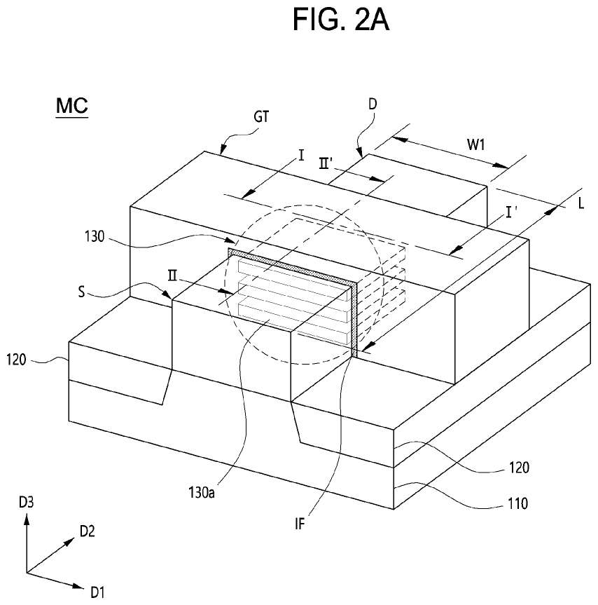

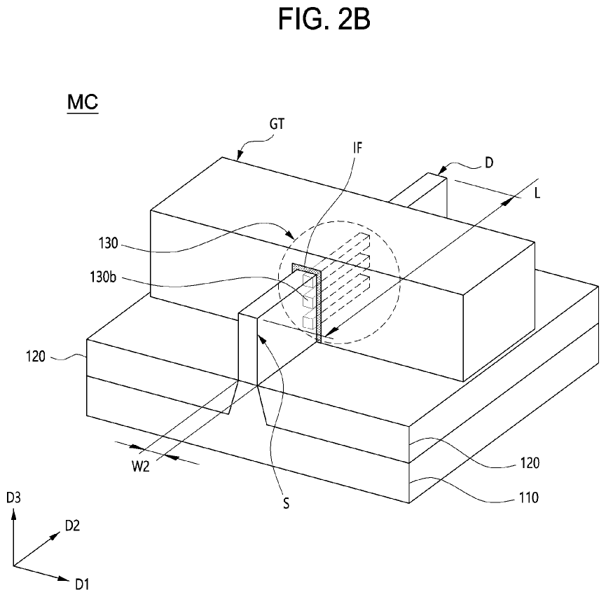

FIGS. 2A and 2B are perspective views illustrating an electrochemical memory cell in accordance with embodiments of the disclosure.

Referring to FIGS. 2A and 2B, an electrochemical memory cell MC may include a channel or a memory region having a gate all around (GAA) structure. The electrochemical memory cell MC may be formed on a lower layer 110.

The lower layer 110 may include at least one semiconductor layer, a semiconductor substrate, and so forth. In example embodiments, the lower layer 110 may include a silicon layer, a single crystalline silicon substrate, and so forth. Alternatively, the lower layer 110 may include Ge, SiC, GaAs, GaP, InP, InAs, InSb, SiGe, GaAsP, AlInAs, AlGaAs, GaInAs, GaInP, GaInAsP, or a combination thereof. Further, the lower layer 110 may include a silicon-on-insulator (SOI) substrate, a silicon germanium-on-insulator (SGOI) substrate, or a germanium-on-insulator (GOI) substrate, and so forth. The lower layer 110 may have an upper surface extending in the first direction D1 and the second direction D2. An isolation layer 120 may be arranged in the lower layer 110 to define an active region. A third direction D3 may be a direction substantially perpendicular to the upper surface of the lower layer 110.

The electrochemical memory cell MC may include a nano pattern structure 130, a gate GT, an interface layer IF, a source S and a drain D.

The nano pattern structure 130 may be operate as a channel region or a memory region of the electrochemical memory cell MC. The nano pattern structure 130 may include at least one nano pattern. The nano pattern structure 130 may include a variable resistance material. For example, the nano pattern structure 130 may include transition metal oxide. Particularly, a transition metal in the transition metal oxide may include at least one of Ta, Sc, Y, Ti, Zr, V, Cr, Nb, Os, Mn, Fe, Ni, Cu, Ag, Zn, Hf and W. Alternatively, the nano pattern structure 130 may include at least one of a unipolar material having a switching characteristic irrelevant to a polarity of an applied voltage and a bipolar material with opposite switching characteristics in different polarities, but examples are not limited thereto.

Further, the material of the nano pattern structure 130 may be determined by the nature of the ions used in memory operations.

For example, when the ions for the memory operation include an oxygen vacancy, the nano pattern structure 130 may include a transition metal oxide layer that satisfies a stoichiometric composition or that is in an oxygen deficiency state.

Alternatively, when the ions for the memory operation include hydrogen ions, the nano pattern structure 130 may include WO₃ or 2D M×ene.

Further, when the ions for the memory operation include a lithium ion, the nano pattern structure 130 may include WO₃, Liₓ₋₁CO₂ or graphene. Hereinafter, electrochemical memory cells MC of example embodiments described below are assumed to use ions with oxygen vacancies for memory operations.

In example embodiments, the nano pattern structure 130 may be a variable resistance pattern having a width, a length and a thickness. For example, each of the width, the length and the thickness may be 0.1 to 50 nanometers (nm).

As shown in FIG. 2A, the nano pattern structure 130 may include a plurality of nano sheets 130a. The plurality of nano sheets 130a may be arranged in the third direction D3 and may be separated from each other by a set gap.

Alternatively, as shown in FIG. 2B, the nano pattern structure 130 may include a plurality of nano wires 130b. The plurality of nano wires 130b may be arranged in the third direction D3 and may be separated from each other by a set gap. A width W1 of the nano sheet 130a may be wider than a width W2 of the nano wire 130b.

For example, the gate GT may extend over the lower layer 110 in the first direction D1. The length of the nano pattern structure 130 may be substantially the same as the dimension of the gate GT in the second direction D2, and the gate GT may surround the nano pattern structure 130 including the plurality of nano sheets 130a or the plurality of nano wires 130b.

As shown in FIG. 2A, the gate GT may be positioned in spaces between the stacked nano sheets 130a, at sidewalls of the nano sheets 130a that extend in the second direction D2, a space between a lowermost nano sheet 130a and the lower layer 110, and over an uppermost nano sheet 130a.

As shown in FIG. 2B, the gate GT may be positioned in spaces between the stacked nano wires 130b, at sidewalls of the nano wires 130b that extend in the second direction D2, a space between a lowermost nano wire 130b and the lower layer 110, and over an uppermost nano wire 130b.

The interface layer IF may be positioned between the nano pattern structure 130 and the gate GT. The interface layer IF may selectively control the flow of the ions for a memory operation resulting from an electric field between the gate GT and the nano pattern structure 130. In an embodiment, the interface layer IF may surround each of the plurality of nano sheets 130a and each of the plurality of nano wires 130b.

For example, the interface layer IF may transfer the ions for a memory operation to the nano pattern structure 130, may receive the ions for a memory operation from the nano pattern structure 130, or may block the transfer of ions for a memory operation based on a direction of the electric field.

In an embodiment, the interface layer IF may include an ion storage layer and an electrolyte layer. The ion storage layer may contact the gate GT. The ion storage layer may generate and store the ions for memory operations.

In an embodiment, when a positive voltage of no less than a threshold voltage is applied to the gate GT, an electrochemical reaction may be induced in the ion storage layer to generate oxygen vacancies. In contrast, when a negative voltage lower than an electric potential of the nano pattern structure 130 is applied to the gate GT, the ion storage layer may receive and store oxygen vacancies from the nano pattern structure 130. The ion storage layer may include a metal compound having an oxygen ion, and oxygen vacancies may be used as ions for memory operations. In some embodiments, the ion storage layer may be a part of the gate GT.

In an embodiment, the electrolyte layer may be positioned between the ion storage layer and the nano pattern structure 130. The electrolyte layer may exchange the ions for the memory operation from the gate GT to the nano pattern structure 130 (or from the nano pattern structure 130 to the gate GT) in accordance with the direction of the electric field. For example, the direction of the electric field may be a direction of an electric force between the gate GT and the nano pattern structure 130. Alternatively, when an electric field between the gate GT and the nano pattern structure 130 is not generated, the electrolyte layer may prevent the ions for the memory operation from diffusing between the gate GT and the nano pattern structure 130. The electrolyte layer may include a high dielectric layer having insulative characteristic.

When the ions for the memory operation include an oxygen vacancy, the electrolyte layer and the ion storage layer may include an oxygen-containing material, such as metal oxide. For example, the ion storage layer may include a material having oxidation potential energy lower than that of the nano pattern structure 130, such as for example, Ta₂O₅, TiO₂, WO₃, and so forth. The electrolyte layer may include at least one of HFOx, ZrO₂, yttria-stabilized zirconia (YSZ).

When the ions for the memory operation include H⁺ ions, the ion storage layer may include may include at least one of Pd(Hx), Mg(Hx) and Y(YHx). The electrolyte layer may include a liquid or an organic electrolyte material such as proton exchange membrane (PEM), nafion membrane, phosphosilicate glass (PSG), and so forth.

When the ions for the memory operation include Li⁺ ions, the ion storage layer may include Li. The electrolyte layer may include an insulation material containing Li. In some embodiments, when the ions for the memory operation include the Li⁺ ion, the ion storage layer may be omitted.

As illustrated, the source S and the drain D may be spaced apart by the gate GT in the second direction D2 and formed on active regions on respective sides of the gate GT. For example, the source S may be connected to one side of the nano pattern structure 130. The source S may protrude in the third direction D3 from the active region. The drain D may be connected to the other side of the nano pattern structure 130. The drain D may protrude in the third direction D3 from the active region. The source S and the drain D may include an epitaxial pattern that grows from the active region. The epitaxial pattern in the source S and the drain D may include conductive impurities.

For example, the source S, the nano pattern structure 130 and the drain D may be positioned on the active region. A length between the source S, the nano pattern structure 130 and the drain D may correspond to a length L in the second direction D2 of the electrochemical memory cell MC.

### Write Operation

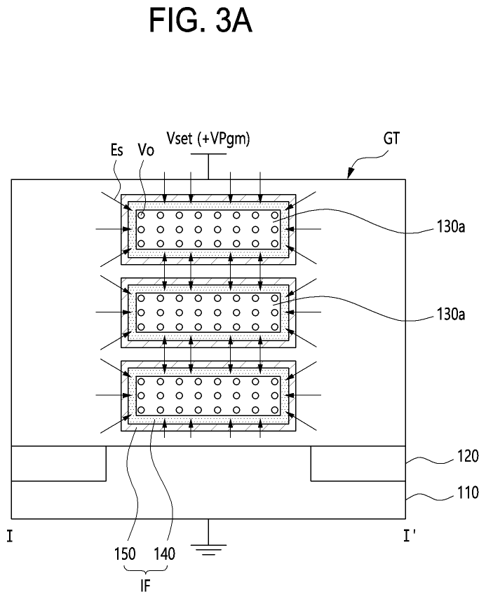

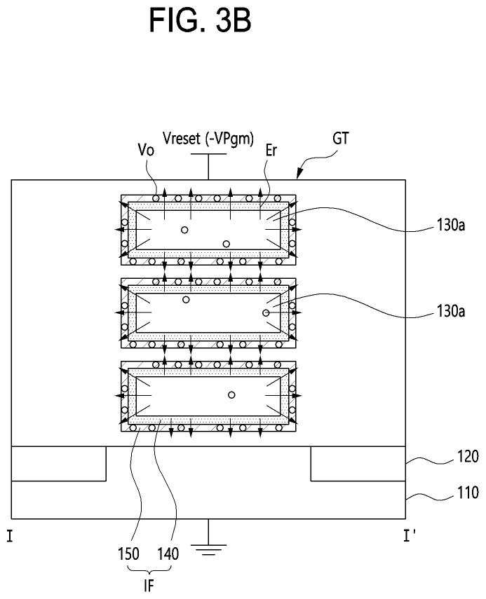

FIGS. 3A and 3B are cross-sectional views illustrating a write operation of an electrochemical memory cell in accordance with embodiments of the disclosure. For example, FIGS. 3A and 3B are cross-sectional views taken along a line I-I′ in FIG. 2A. The stacked nano sheets 130a may be used in a channel of the electrochemical memory cell MC. The operation of the electrochemical memory cell may use an oxygen vacancy as ions for memory operations.

Referring to FIGS. 1, 2A and 3A, a positive program voltage +Vpgm, i.e., a set voltage Vset may be applied to the gate GT. A ground voltage may be applied to the source S and the drain D. The lower layer 110 under the nano sheets 130a, for example, the active region, may also have the ground voltage level by the voltage applied to the source S and the drain D.

The set voltage Vset may be applied to the gate GT through a selected word line. The ground voltage may be applied to the source S, the drain D and the lower layer 110 through the source line SL and the bit line BL.

The set voltage Vset may be higher than a threshold voltage Vth. The threshold voltage Vth may be a minimum voltage for inducing an electrochemical reaction in the gate GT, the ion storage layer 150 and the nano sheets 130a. When the set voltage Vset is applied to the gate GT and the ion storage layer 150, an electrochemical reaction may be generated among the gate GT, the ion storage layer 150, and the nano sheet 130a. Ions for the memory operation may be generated from the ion storage layer 150 and the gate GT. In example embodiments, the ions for the memory operation may include the oxygen vacancies and/or the oxygen ions.

As shown in FIG. 3A, an electric field Es may be generated by a voltage difference between the gate GT and the nano sheets 130a. The oxygen vacancies Vo generated from the gate GT and the ion storage layer 150 may be transferred to the nano sheet 130a through the electrolyte layer 140. The oxygen ions in the nano sheet 130a may be transferred to the ion storage layer 150 through the electrolyte layer 140 in an exchange of oxygen vacancies and oxygen ions.

In FIG. 3A, all outer surfaces of the nano sheets 130a may be surrounded by the gate GT and the interface layer IF. As a result, exchanges of the oxygen vacancies and the oxygen ions may be generated in all directions, and the oxygen vacancies Vo may be distributed in the nano sheets 130a along all directions. Thus, an electrochemical reaction generated in nano sheet 130a as the channel may be generated to changes a conductivity of a channel, i.e., a nano sheet 130a. Therefore, when the nano sheets 130a have a resistance lower than a reference resistance, the electrochemical memory cell MC may be switched into a low resistance state, i.e., a set state.

As described above, all the surfaces of the nano sheet 130a as the channel may be surrounded by the gate GT and the interface layer IF. Thus, nano sheets 130a may receive the oxygen vacancies Vo through all the surfaces of the nano sheets 130a common to gate GT. Therefore, the nano sheets 130a may be switched into the set state more rapidly than a 2D planer type channel structure.

Further, the nano sheets 130a may have a limited volume, which is different from the 2D planar type channel structure. Thus, the ions for the memory operation may be rapidly and effectively supplied to the nano sheets 130a from various directions to induce the electrochemical reaction more quickly.

As a result, the set voltage may be applied for a shorter amount of time while securing a set switching characteristic. Thus, the electrochemical memory cell MC of example embodiments may have low power consumption and a faster operation speed.

Referring to FIGS. 1, 2A and 3B, a ground voltage may be applied to the source S and the drain D to maintain the nano sheet 130a at the ground voltage level. A negative program voltage-Vpgm, i.e., a reset voltage Vreset may be applied to the gate GT.

The oxygen ions in the gate GT and the ion storage layer 150 may be increased by the reset voltage Vreset so that the gate GT and the ion storage layer 150 enters a deficiency state with respect to oxygen vacancies.

Further, as shown in FIG. 3B, a reset electric field Er may be generated from the nano sheet 130a having a relatively high electric potential to the gate GT having a relatively low electric potential. Thus, the oxygen vacancies Vo in the nano sheets 130a may be transferred to the ion storage layer 150 (and the gate GT) by the reset electric field Er.

The nano sheets 130a may have a resistance higher than the reference resistance because of the transfer of the oxygen vacancies Vo. Thus, the electrochemical memory cell MC may be switched to a high resistance state, i.e., a reset state.

Because the reset electric field Er may be generated in the all directions of the nano sheets 130a, the oxygen vacancies Vo in the nano sheets 130a may be rapidly transferred to the ion storage layer 150 in various directions to radically increase channel resistance. Thus, the time required for applying the reset voltage may be reduced to provide an electrochemical memory cell MC with lower power consumption and rapid operation speed.

In example embodiments, an electrochemical memory cell may be written to a low resistance state and a high resistance state by exchanging oxygen vacancies and oxygen ions, but embodiments are not limited thereto. For example, hydrogen ions or lithium ions may be used for the ions for the memory operation.

### Read Operation

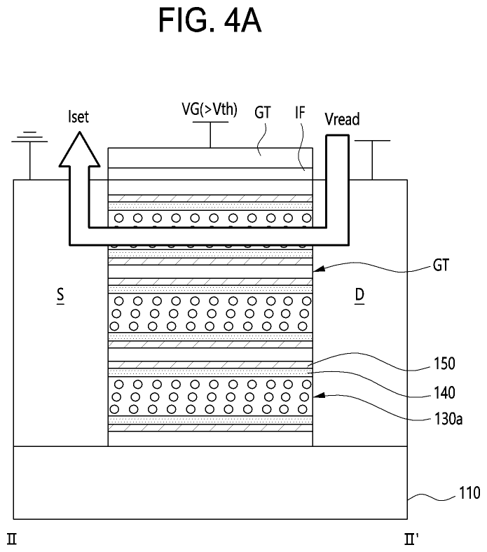

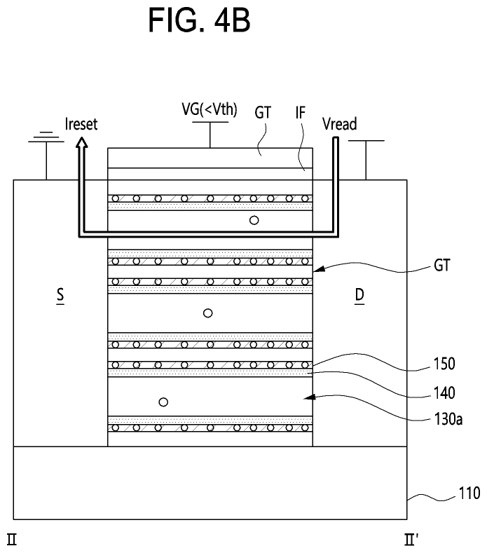

FIGS. 4A and 4B are cross-sectional views illustrating a read operation of an electrochemical memory cell in accordance with embodiments of the disclosure. For example, FIGS. 4A and 4B are cross-sectional views taken along a line II-II′ in FIG. 2A.

Referring to FIGS. 1, 2A, 3A, 3B, 4A and 4B, in order to sense data in an electrochemical memory cell MC, a read voltage Vread may be applied to a drain D and a ground voltage may be applied to a source S. A gate voltage VG may be no more than a threshold voltage Vth, which may be for example, the ground voltage. The read voltage Vread may have no influence on the resistance of nano sheets 130a. For example, the read voltage Vread may generate a current from the drain D to the source S without a change of the resistance in the nano sheets 130a.

For example, as shown in FIG. 3A, when a set voltage Vset is applied to a gate GT, ions for a memory operation, such as oxygen vacancies Vo, transfer from the gate GT and an ion storage layer 150 to nano sheets 130a.

Then, as shown in FIG. 4A, when the gate voltage VG decreases to no more than the threshold voltage Vth and the read voltage Vread may be applied to the drain D, a channel may be generated between the drain D, the nano sheet 130a and the source S. A current flowing through the channel, that is, an output current of the electrochemical memory cell MC may be greater than a reference current, and the current may be determined as a set current Iset. For example, a sensing device (not shown) may read the set data of the electrochemical memory cell MC.

Referring to FIG. 3B, when a reset voltage Vreset is applied to the gate GT, an electrochemical reaction may occur in nano sheets 130a. And then, as shown in FIG. 4B, the gate voltage VG may be decreased to no more than the threshold voltage Vth and the read voltage Vread may be applied to the drain D. A current flowing through the drain, the nano sheet 130a and the source S, that is, an output current of the electrochemical memory cell MC, may be determined to be a reset current Ireset, which is less than the reference current. Thus, the sensing device (not shown) may read the reset data of the electrochemical memory cell MC. The sensing device may include a sense amplifier electrically connected to the source S (or the drain D).

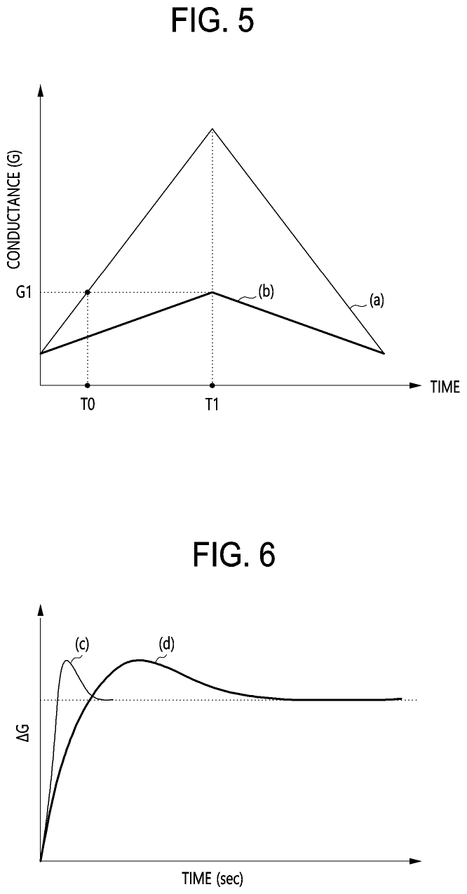

FIG. 5 is a graph showing a conductance of a memory cell in accordance with an embodiment of the disclosure and FIG. 6 is a graph showing variances of a conductance of a memory cell in accordance with an embodiment of the disclosure.

Referring to FIG. 5, under the same conditions, an operation voltage, such as for example a program voltage (set voltage), may be applied to a gate of an electrochemical memory cell (a) with nano sheets 130a of disclosed embodiments and a gate of an electrochemical memory cell (b) with a 2D planar channel of a comparative device.

After lapsed a time T1, a conductance of the electrochemical memory cell (a) with the nano sheets 130a of disclosed embodiments may be markedly increased compared to a conductance of the electrochemical memory cell (b) with the 2D planar channel.

Thus, when the same program voltage is applied, it can be noted that a set/reset ratio (on/off efficiency) of the electrochemical memory cell (a) with the nano sheets 130a of disclosed embodiments is improved compared to that of the electrochemical memory cell (b) with the 2D planar channel over the same amount of time.

Further, as shown in FIG. 5, the electrochemical memory cell (a) with the nano sheets 130a of example embodiments may take a shorter time TO than the time T1 for securing a conductance G1, which is the maximum conductance of the electrochemical memory cell (b) with the 2D planar channel. Thus, it can be noted that the electrochemical memory cell (a) with the nano sheets 130a has a greater operation speed over the operation speed of the electrochemical memory cell (b) with the 2D planar channel. As a result, the electrochemical memory cell (a) with the nano sheets 130a of disclosed embodiments may be driven by lower amounts of power.

As shown in FIG. 6, a variance ΔG of a conductance G in an electrochemical memory cell (c) with the nano sheets 130a of disclosed embodiments may be rapidly changed compared to that of an electrochemical memory cell (d) with a 2D planar channel. Thus, the electrochemical memory cell (c) with the nano sheets 130a of disclosed embodiments may have an operation speed that is faster than the operation speed of the electrochemical memory cell (d) with the 2D planar channel.

In some embodiments, a memory cell of a neural network memory device may include an electrochemical memory cell with the nano pattern. The ions for a memory operation may be exchanged with each other through all the surfaces of the nano pattern common to a corresponding gate to achieve a high conductance in a short amount of time and to induce a rapid conductance change. Therefore, the neural network memory device with such electrochemical memory cells may have lower power drive and the higher operation speed.

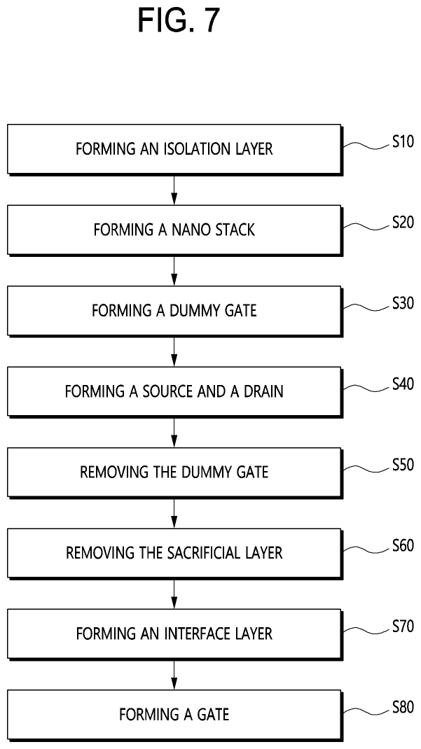

FIG. 7 is a flow chart illustrating a method of manufacturing an electrochemical memory cell in accordance with an embodiment of the disclosure.

Referring to FIGS. 2A, 2B and 7, in step S10, an isolation layer 120 may be formed in a lower layer 110. For example, the isolation layer 120 may be formed by a shallow trench isolation (STI) process. The isolation layer 120 may define an active region in the lower layer 110.

At least one sacrificial layer (not shown) and at least one variable resistance layer (not shown) may be alternately stacked over the lower layer 110, in a third direction D3 substantially perpendicular to the upper surface of the lower layer 110. For example, the sacrificial layer may include a material having an etching selectivity with respect to the variable resistance layer. In step S20, the sacrificial layer and the variable resistance layer may be patterned to form a nano stack (not shown) including the sacrificial patterns and the variable resistance patterns, which are alternately stacked. For example, the nano stack may have 0.1 to 50 nm of a width (for example, a channel length). The nano stack may be positioned over the active region. A lowermost portion of the nano stack may be a sacrificial layer and an uppermost portion of the nano stack may be a variable resistance layer. Further, the nano stack may have a width (e.g., W1 or W2) extending in the first direction D1 and a length extending in the second direction D2. For example, the length of the nano stack may correspond to a length L of the electrochemical memory cell MC in FIGS. 2A and 2B.

In step S30, a dummy gate may be formed over the lower layer 110. The dummy gate may be formed to intersect with the nano stack. For example, the dummy gate may be extended in the first direction D1. In example embodiments, the dummy gate may include a material having an etching selectivity with respect to the nano stack, the isolation layer 120 and the lower layer 110. A spacer may be formed on a sidewall of the dummy gate. A width of the spacer may control a distance between the region blocked by the dummy gate where a channel region may be formed and regions where the source and the drain may be formed.

The nano stack may be etched using the dummy gate, or the dummy gate with the spacer as a mask, to open the active region. In step S40, the source S and the drain D may be formed on the exposed active region. In example embodiments, the active region may be epitaxial grown to form an epitaxial pattern. Further, the epitaxial pattern may be doped with conductive impurities. After doping the epitaxial pattern with the conductive impurities, a transition metal silicide layer may be formed thereby forming the source S and the drain D.

In step S50, the dummy gate may be removed. In embodiments, the dummy gate may be removed using an etchant having an etching selectivity with respect to the remaining nano stack, the source S, the drain D, the isolation layer 120 and the lower layer 110.

In step S60, the sacrificial layer of the nano stack may be removed to form the nano pattern structure 130. Thus, the nano pattern structure 130 includes the plurality of nano sheets 130a (or a plurality of nano wires 130b) spaced apart from each other by substantially uniform gaps. All the surfaces of the nano pattern structure 130 that are not in contact with the source S or drain D may be exposed.

In step S70, an interface layer IF may be formed on the surfaces of the exposed nano pattern structure 130. The interface layer IF may include the electrolyte layer 140 and the ion storage layer 150. At least one of the electrolyte layer 140 and the ion storage layer 150 may be formed by an atomic layer deposition (ALD) process, a metal organic chemical vapor deposition (MOCVD) process, etc., but not limited thereto.

A conductive layer including a metal may be formed on the interface layer IF to form the gate GT. The conductive with the metal may be replaced at a region where the dummy gate may be removed to form the gate GT.

The above described embodiments of the present invention are intended to illustrate and not to limit the present invention. Various alternatives and equivalents are possible. The invention is not limited by the embodiments described herein. Nor is the invention limited to any specific type of semiconductor device. Another additions, subtractions, or modifications are obvious in view of the present disclosure and are intended to fall within the scope of the appended claims.

What is claimed is:

1. An electrochemical memory cell comprising:
a plurality of nano patterns arranged over an active region to have a set gap between adjacent nano patterns;
a gate configured to surround upper, lower and sidewall surfaces of each of the nano patterns; and
an interface layer disposed between the nano patterns and the gate,
wherein the nano patterns comprise a variable resistance material.

2. The electrochemical memory cell of claim 1, wherein the interface layer comprises an electrolyte layer configured to exchange ions with the nano patterns in accordance with a voltage applied to the gate in a memory operation.

3. The electrochemical memory cell of claim 2, wherein at least one of the electrolyte layer and the gate comprises an ion component and a metal.

4. The electrochemical memory cell of claim 2, wherein the electrolyte layer comprises an insulation material.

5. The electrochemical memory cell of claim 2, wherein the interface layer further comprises an ion storage layer disposed between the electrolyte layer and the gate.

6. The electrochemical memory cell of claim 1, further comprising:
a source disposed on the active region and connected to one side of the nano patterns; and
a drain disposed on the active region and connected to the other side of the nano patterns.

7. The electrochemical memory cell of claim 1, wherein at least one of the nano patterns, the gate and the interface layer comprises a material configured to generate ions in an electrochemical reaction based on a voltage applied to the gate.

8. A neural network memory device comprising:
a plurality of electrochemical memory cells, each of the electrochemical memory cells comprising:
a lower layer including an active region extending in a second direction and having an upper surface extending in a first direction and the second direction;
a channel region in a selected portion of the active region;
a source arranged on the active region common to one end of the channel region;
a drain arranged on the active region common to the other end of the channel region;
a gate extending in the first direction to surround surfaces of the channel region that are not common to the source and the drain; and
an interface layer between the channel region and the gate,
wherein the channel region comprises a plurality of variable resistance patterns stacked in a third direction that is substantially perpendicular to the upper surface of the lower layer.

9. The neural network memory device of claim 8, wherein the gate and the interface layer are between the variable resistance patterns, between a lowermost variable resistance pattern and the active region, and between an uppermost variable resistance pattern and the gate.

10. The neural network memory device of claim 8, wherein the interface layer comprises:
an electrolyte layer on the variable resistance patterns and including an insulation material; and
an ion storage layer between the electrolyte layer and the gate that generates ions based on a direction of an electric field between the channel region and the gate and that receives and stores ions from the variable resistance patterns.

11. The neural network memory device of claim 10, wherein the electrolyte layer transfers, exchanges or blocks ions between the gate and the variable resistance patterns based on the electric field.

12. The neural network memory device of claim 10, wherein the variable resistance patterns, the gate and the ion storage layer comprise a material that generates ions in an electrochemical reaction in accordance with the electric field.

13. The neural network memory device of claim 12, wherein the ion storage layer comprises a material having an oxidation potential energy lower than an oxidation potential energy of the variable resistance patterns.

14. The neural network memory device of claim 8, wherein each of the variable resistance patterns has a width extending in the first direction and a length extending in the second direction, and the width and the length of the variable resistance patterns is 0.1 to 50 nano meter.

15. The neural network memory device of claim 8, wherein at least one of the source and the drain comprises an epitaxial pattern.

16. The neural network memory device of claim 8, further comprising:
at least one word line extending in the first direction and connected to the gate;
at least one bit line extending in the second direction and connected to the drain; and
at least one source line extending in at least one of the first and second directions and connected to the source,
wherein the electrochemical memory cells are positioned at intersected portions between the word line and the bit line.
